(19) United States
(12) Patent Application Publication
(10) Pub. No.: US 2024/0107811 A1
(43) Pub. Date: Mar. 28, 2024

(54) DISPLAY APPARATUS

(71) Applicant: SAMSUNG DISPLAY CO., LTD., Yongin-si (KR)

(72) Inventors: Hyuneok SHIN, Yongin-si (KR); Joonwoo BAE, Yongin-si (KR)

(21) Appl. No.: 18/137,656

(22) Filed: Apr. 21, 2023

(30) Foreign Application Priority Data
Sep. 28, 2022 (KR) 10-2022-0123476

(51) Int. Cl. H10K 59/121; H10K 59/122

(52) U.S. Cl. CPC H10K 59/1216; H10K 59/1213; H10K 59/122

(57) ABSTRACT

A display apparatus includes a substrate including a trench, a capacitor disposed on the substrate in the trench, a bottom metal layer disposed on the substrate and spaced apart from the capacitor, and a thin-film transistor disposed on the bottom metal layer, where the capacitor includes a first metal layer, a second metal layer, and an inorganic insulating layer, the first metal layer is disposed in a same layer as the bottom metal layer, the second metal layer is disposed on the first metal layer, and the inorganic insulating layer is disposed between the first metal layer and the second metal layer.

This application claims priority to Korean Patent Application No. 10-2022-0123476, filed on Sep. 28, 2022, and all the benefits accruing therefrom under 35 U.S.C. § 119, the content of which in its entirety is herein incorporated by reference.

### BACKGROUND

### 1. Field

One or more embodiments relate to a display apparatus.

### 2. Description of the Related Art

Display apparatuses such as organic light-emitting display apparatuses, liquid crystal display apparatuses, and the like may include an array substrate including a thin-film transistor (TFT), a capacitor, and a plurality of wirings. The array substrate typically includes fine patterns of TFTs, capacitors, wirings, and the like. Display apparatuses including such an array substrate may operate based on complex connections between the TFTs, the capacitors, and the wirings.

### SUMMARY

Recently, as the demand for compact and high-resolution display apparatuses increases, efficient spatial arrangement between TFTs, capacitors and wirings included in such display apparatuses, improvement of a connection structure therein, improvement of a driving method thereof, and improvement of image quality are desired.

One or more embodiments include a display apparatus with improved characteristics of a transistor and a secured capacity of a capacitor. However, such a technical problem is an example, and the disclosure is not limited thereto.

According to one or more embodiments, a display apparatus includes a substrate including a trench, a capacitor disposed on the substrate in the trench, a bottom metal layer disposed on the substrate and spaced apart from the capacitor, and a thin-film transistor disposed on the bottom metal layer, where the capacitor includes a first metal layer, a second metal layer, and an inorganic insulating layer, the first metal layer is disposed in a same layer as the bottom metal layer, the second metal layer is disposed on the first metal layer, and the inorganic insulating layer is disposed between the first metal layer and the second metal layer.

In an embodiment, a portion of the capacitor may have a shape corresponding to a shape of the trench.

In an embodiment, the second metal layer may include titanium (Ti).

In an embodiment, the display apparatus may further include a filling layer disposed on the second metal layer and filling a region on the second metal layer corresponding to the trench.

In an embodiment, the filling layer may include a spin-on-glass (SOG) material.

In an embodiment, the trench may have an elliptical shape in a plan view.

In an embodiment, the trench may be provided in plural.

In an embodiment, each of a plurality of trenches may have an elliptical shape in a plan view, and the trenches may be apart from each other in the plan view.

In an embodiment, the second metal layer may be connected to a connection electrode layer disposed on the thin-film transistor through a contact hole.

In an embodiment, the connection electrode layer may include a data line, and the second metal layer may be electrically connected to the data line.

In an embodiment, the thin-film transistor may include an oxide semiconductor.

According to one or more embodiments, a display apparatus includes a substrate including a trench, a capacitor on the substrate, where the capacitor includes a first metal layer, an inorganic insulating layer, and a second metal layer sequentially disposed on the substrate along a shape of the trench, and a filling layer disposed on the second metal layer and filling a region on the second metal layer corresponding to the trench, where the filling layer includes a spin-on-glass (SOG) material.

In an embodiment, the display apparatus may further include a thin-film transistor disposed on the substrate.

In an embodiment, the thin-film transistor may include an oxide semiconductor.

In an embodiment, the display apparatus may further include a bottom metal layer disposed between the substrate and the thin-film transistor.

In an embodiment, the first metal layer may be disposed in a same layer as the bottom metal layer.

In an embodiment, the display apparatus may further include a connection electrode layer disposed on the second metal layer and the thin-film transistor, where the connection electrode layer may be electrically connected to the second metal layer.

In an embodiment, the second metal layer may include a same material as a material of the connection electrode layer.

In an embodiment, the trench may be provided in plural.

In an embodiment, each of a plurality of trenches may have an elliptical shape in a plan view, and the trenches may be apart from each other in the plan view.

In an embodiment, the display apparatus may further include a pixel electrode disposed on the connection electrode layer, a pixel-defining layer disposed on the pixel electrode, where an opening may be defined through the pixel-defining layer to expose a portion of the pixel electrode, an intermediate layer filling the opening, and an opposite electrode disposed on the intermediate layer.

### BRIEF DESCRIPTION OF THE DRAWINGS

The above and other features of certain embodiments of the disclosure will be more apparent from the following description taken in conjunction with the accompanying drawings, in which:

FIG. 1 is a schematic plan view of a portion of a display apparatus according to an embodiment;

FIGS. 2A and 2B are equivalent circuit diagrams of a pixel of a display apparatus according to an embodiment;

FIG. 3 is a schematic cross-sectional view of a display apparatus according to an embodiment;

FIG. 4 is a schematic cross-sectional view of a display apparatus according to an alternative embodiment; and

FIGS. 5A and 5B are plan views of a display apparatus according to embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be further understood that, when a layer, region, or element is referred to as being “on” another layer, region, or element, it can be directly or indirectly on the other layer, region, or element. That is, for example, intervening layers, regions, or elements may be present.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the present specification, “A and/or B” means A or B, or A and B.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

It will be understood that when a layer, region, or element is referred to as being “connected” to another layer, region, or element, it may be “directly connected” to the other layer, region, or element or may be “indirectly connected” to the other layer, region, or element with other layer, region, or element interposed therebetween. For example, it will be understood that when a layer, region, or element is referred to as being “electrically connected” to another layer, region, or element, it may be “directly electrically connected” to the other layer, region, or element or may be “indirectly electrically connected” to other layer, region, or element with other layer, region, or element interposed therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

A display apparatus is an apparatus configured to display images and may include liquid crystal displays, electrophoretic displays, organic light-emitting displays, inorganic light-emitting displays, quantum-dot light-emitting displays, field emission displays, surface-conduction electron-emitter displays, plasma displays, or the like.

Hereinafter, embodiments will be described with reference to the accompanying drawings, in which like reference numerals refer to like elements throughout and any repetitive detailed description thereof is omitted. Hereinafter, for convenience of description, embodiments where the display apparatus is an organic light-emitting display apparatus will be described in detail, but the display apparatus according to embodiments is not limited thereto and alternatively, the display apparatus may be another type of various types of display apparatus known in the art.

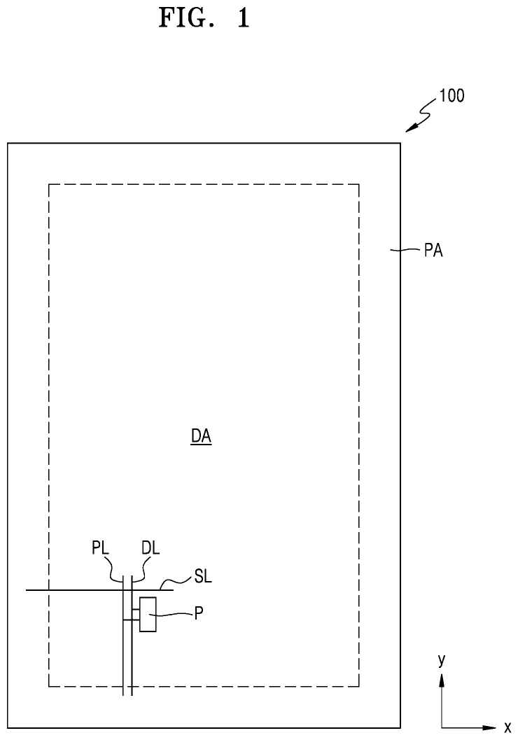

FIG. 1 is a schematic plan view of a display apparatus according to an embodiment.

Referring to FIG. 1, in an embodiment, a substrate 100 of the display apparatus may be divided into a display area DA and a peripheral area PA around the display area DA. The display apparatus may be configured to display images by using light emitted from a plurality of pixels P arranged in the display area DA.

Each pixel P includes a display element such as an organic light-emitting diode and may be configured to emit, for example, red, green, blue, or white light. In an embodiment, each pixel P may be connected to a pixel circuit including a thin-film transistor TFT, a capacitor, or the like. The pixel circuit may be connected to a scan line SL, a data line DL crossing the scan line SL, and a driving voltage line PL. The scan line SL may extend in a first direction (or an x direction), the data line DL and the driving voltage line PL may extend in a second direction (or a y direction) crossing the first direction.

When the pixel circuit is driven, each pixel P may be configured to emit light, and the display area DA may be configured to display a preset image using light emitted from the pixels P. In such an embodiment, as described above, the pixel P may be defined as an emission area configured to emit light having one of red, green, blue, and white.

The peripheral area PA is a region in which the pixels P are not arranged and may be a region that does not display images. A printed circuit board, a terminal part, and the like may be arranged in the peripheral area PA, where the printed circuit board includes a built-in driving circuit part, a power supply line, and a driving circuit part configured to drive the pixels P, and a driver integrated circuit (IC) is connected to the terminal part.

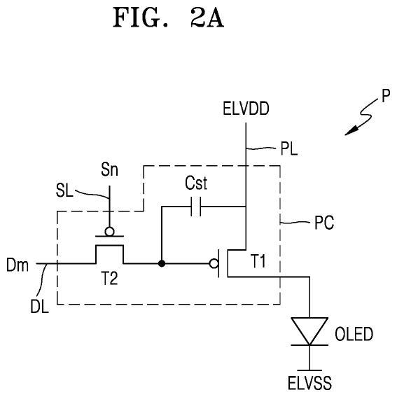

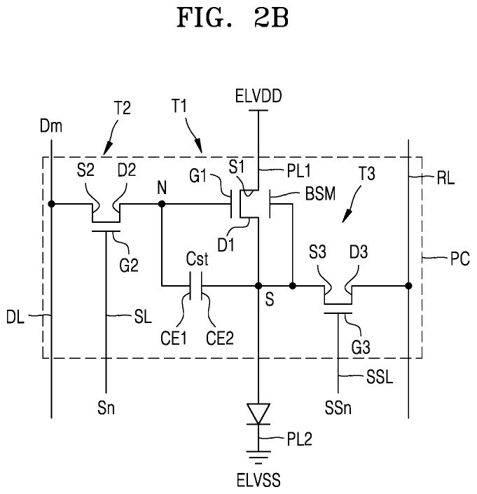

FIGS. 2A and 2B are equivalent circuit diagrams of a pixel of the display apparatus according to an embodiment.

Referring to FIG. 2A, in an embodiment, each pixel P may include a pixel circuit PC and an organic light-emitting element OLED connected to the pixel circuit PC, where the pixel circuit PC is connected to the scan line SL and the data line DL.

The pixel circuit PC may include a driving thin-film transistor T1, a switching thin-film transistor T2, and a capacitor Cst. The switching thin-film transistor T2 may be connected to the scan line SL and the data line DL, and configured to transfer a data signal Dm to the driving thin-film transistor T1 in response to a scan signal Sn, where the data signal Dm is input through the data line DL, and the scan signal Sn is input through the scan line SL.

The capacitor Cst may be connected to the switching thin-film transistor T2 and the driving voltage line PL and configured to store a voltage corresponding to a difference between a voltage transferred from the switching thin-film transistor T2 and a first power voltage ELVDD (or a driving voltage) supplied to the driving voltage line PL.

The driving thin-film transistor T1 may be connected to the driving voltage line PL and the capacitor Cst and configured to control a driving current based on the voltage stored in the capacitor Cst, such that the driving current may flow from the driving voltage line PL to the organic light-emitting element OLED. The organic light-emitting element OLED may be connected to a second power voltages ELVSS, which is lower than the first power voltage ELVDD. The organic light-emitting element OLED may be configured to emit light having a preset brightness corresponding to the driving current.

FIG. 2A shows an embodiment where the pixel circuit PC includes two thin-film transistors and a single capacitor, but the embodiment is not limited thereto.

Referring to FIG. 2B, in an alternative embodiment, each pixel P may include an organic light-emitting element OLED and the pixel circuit PC driving the organic light-emitting element OLED, where the pixel circuit PC includes a plurality of thin-film transistors. The pixel circuit PC may include the driving thin-film transistor T1, the switching thin-film transistor T2, a sensing thin-film transistor T3, and the capacitor Cst.

The scan line SL may be connected to a gate electrode G2 of the switching thin-film transistor T2, the data line DL may be connected to a source electrode S2 of the switching thin-film transistor T2, and a first electrode CE1 of the capacitor Cst may be connected to a drain electrode D2 of the switching thin-film transistor T2.

Accordingly, the switching thin-film transistor T2 may be configured to supply a data voltage of the data line DL to a first node N in response to a scan signal Sn from the scan line SL of each pixel P.

A gate electrode G1 of the driving thin-film transistor T1 may be connected to the first node N, a source electrode S1 of the driving thin-film transistor T1 may be connected to a first power voltage line PL1 configured to transfer the first power voltage ELVDD, and a drain electrode D1 of the driving thin-film transistor T1 may be connected to an anode electrode of the organic light-emitting element OLED.

Accordingly, the driving thin-film transistor T1 may be configured to adjust the amount of a current flowing through the organic light-emitting element OLED based on a source-gate voltage of itself, that is, a voltage applied between the first power voltage ELVDD and the first node N.

A sensing control line SSL is connected to a gate electrode G3 of the sensing thin-film transistor T3, a source electrode S3 of the sensing thin-film transistor T3 is connected to a second node S, and a drain electrode D3 of the sensing thin-film transistor T3 is connected to a reference voltage line RL. In an alternative embodiment, the sensing thin-film transistor T3 may be controlled by the scan line SL instead of the sensing control line SSL.

The sensing thin-film transistor T3 may sense an electric potential of an anode electrode AD of the organic light-emitting element OLED. The sensing thin-film transistor T3 may be configured to supply a pre-charging voltage from the reference voltage line RL to the second node S in response to a sensing signal SSn from the sensing control line SSL, or supply a voltage of the anode electrode AD of the organic light-emitting element OLED to the reference voltage line RL during a sensing period.

The first electrode CE1 of the capacitor Cst is connected to the first node N, and a second electrode CE2 of the capacitor Cst is connected to the second node S. The capacitor Cst is charged with a voltage difference between voltages respectively supplied to the first and second nodes N and S, and is configured to supply the voltage difference as a driving voltage of the driving thin-film transistor T1. In an embodiment, for example, the capacitor Cst may be charged with a voltage difference between a data voltage Dm and a pre-charging voltage respectively supplied to the first and second nodes N and S.

A bias electrode BSM may be formed to correspond to the driving thin-film transistor T1 and connected to the source electrode S3 of the sensing thin-film transistor T3. Because the bias electrode BSM receives a voltage in cooperation with the potential of the source electrode S3 of the sensing thin-film transistor T3, the driving thin-film transistor T1 may be stabilized. In an alternative embodiment, the bias electrode BSM may not be connected to the source electrode S3 of the sensing thin-film transistor T3 but may be connected to a separate bias line.

An opposite electrode (e.g., a cathode) of the organic light-emitting element OLED is configured to receive a second power voltage ELVSS. The organic light-emitting element OLED may be configured to emit light by receiving the driving current from the driving thin-film transistor T1.

FIG. 2B shows an embodiment where signal lines, that is, the scan line SL, the sensing control line SSL, and the data line DL, a reference voltage line RL, the first power line PL1, and a second power line PL2 are provided to each pixel P, but the embodiment is not limited thereto. In an alternative embodiment, for example, at least one of the signals lines, that is, the scan line SL, the sensing control line SSL, and the data line DL, and/or the reference voltage line RL, the first power line PL1, and a second power line PL2 may be shared by adjacent pixels P.

The number of thin-film transistors, the number of capacitors, and the circuit design of the pixel circuit PC are not limited to those described with reference to FIGS. 2A and 2B, and the number of thin-film transistors, the number of capacitors, and the circuit design may be variously changed or modified.

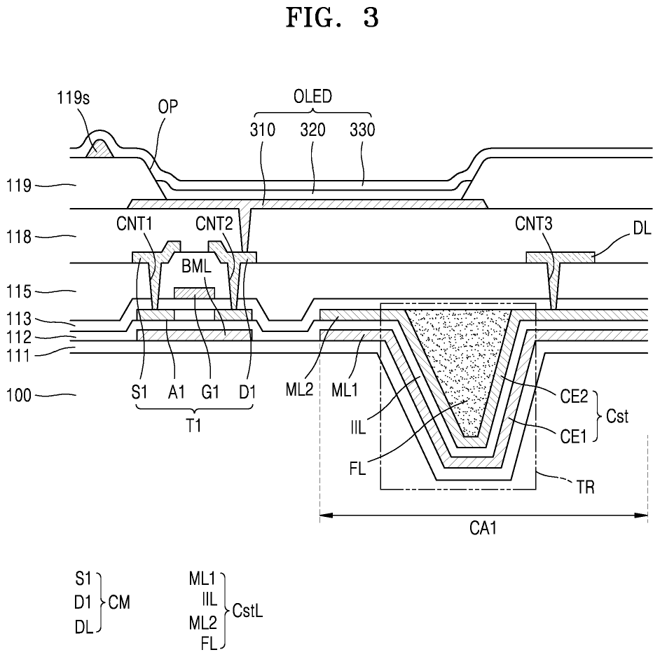

FIG. 3 is a schematic cross-sectional view of a display apparatus according to an embodiment.

Referring to FIG. 3, the display apparatus according to an embodiment may include the substrate 100 including a trench TR, the capacitor Cst, the driving thin-film transistor T1, a connection electrode layer CM, the organic light-emitting element OLED, and a thin-film encapsulation layer 400.

The substrate 100 may include a glass material, a ceramic material, metal, or a flexible or bendable material. In an embodiment where the substrate 100 is flexible or bendable, the substrate 100 may include a polymer resin including polyethersulphone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate (CAP). The substrate 100 may have a single-layered structure or a multi-layered structure, each layer therein including at least one selected from the above materials, and may further include an inorganic layer in an embodiment where the substrate 100 has the multi-layered structure. In an embodiment, for example, the substrate 100 may have a structure of an organic material/an inorganic material/an organic material.

The substrate 100 may include the trench TR. The trench TR may be a region concaved in a depth direction from the upper surface of the substrate 100. The width of the trench TR may be reduced in the depth direction of the substrate 100, that is, decreasing as being away from a top surface (or an uppermost surface) of the substrate 100. The trench TR may be formed by forming a photoresist pattern on the substrate 100 through a photolithography process and then patterning the substrate 100 through an etching process that uses the photoresist pattern as a mask.

A depth TH of the trench TR may be about 10% or less of a thickness of the substrate 100. The depth TH of the trench may be in a range of about 0.5 micrometer (μm) to about 2.5 μm. The trench TR may overlap the capacitor Cst described below.

A first buffer layer 111 may increase the flatness of the upper surface of the substrate 100 (or provide a flat or planarized upper surface on the substrate 100) and include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The first buffer layer 111 may be arranged along the shape of the trench TR of the substrate 100. A portion of the first buffer layer 111 may be disposed inside the trench TR. That is, the first buffer layer 111 may overlap the trench TR. Alternatively, the first buffer layer 111 may be omitted depending on the kind of the substrate 100 and a process condition.

A barrier layer (not shown) may be further disposed between the substrate 100 and the first buffer layer 111. The barrier layer may prevent or reduce the penetration of impurities from the substrate 100 or the like to a semiconductor layer A1. The barrier layer may include an inorganic material, an organic material, or an organic/inorganic composite material, and have a single-layered structure or a multi-layered structure, each layer therein including at least one selected an inorganic material and an organic material, where the inorganic material may include oxide or nitride.

A bottom metal layer BML and a first metal layer ML1 may be disposed on the first buffer layer 111. The bottom metal layer BML and the first metal layer ML1 may include a light-blocking material. The bottom metal layer BML and the first metal layer ML1 may include at least one selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In an embodiment, the bottom metal layer BML may have a molybdenum-single layer, a double-layered structure in which a molybdenum layer and a titanium layer are stacked, or a triple-layered structure in which a titanium layer, an aluminum layer, and a titanium layer are stacked.

The bottom metal layer BML may be arranged to correspond to the driving thin-film transistor T1. A voltage may be applied to the bottom metal layer BML. In an embodiment, the bottom metal layer BML may serve as a bias electrode BMS of FIG. 2B. In such an embodiment, for example, the bottom metal layer BML may be connected to the source electrode S3 (see FIG. 2B) of the sensing thin-film transistor T3 (see FIG. 2B), and the voltage of the source electrode S3 may be applied to the bottom metal layer BML. In addition, the bottom metal layer BML may prevent external light reaching the semiconductor layer A1. Accordingly, the characteristics of the driving thin-film transistor T1 may be stabilized.

The first metal layer ML1 may be disposed in (or directly on) a same layer as the bottom metal layer BML. The first metal layer ML1 may be arranged along the shape of the trench TR of the substrate 100. A portion of the first metal layer ML1 may be disposed inside the trench TR. That is, the first metal layer ML1 may overlap the trench TR. The first metal layer ML1 may be the first electrode CE1 of the capacitor Cst.

A second buffer layer 112 may cover the bottom metal layer BML including the first metal layer ML1 and be formed on the substrate 100 entirely (or disposed over an entire upper surface the substrate 100). The second buffer layer 112 may be arranged along the shape of the trench TR of the substrate 100. A portion of the second buffer layer 112 may be disposed inside the trench TR. That is, the second buffer layer 112 may overlap the trench TR. The second buffer layer 112 may be an inorganic insulating layer IIL and may serve as a dielectric layer of the capacitor Cst.

The second buffer layer 112 may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂).

The semiconductor layer A1 and a second metal layer ML2 may be disposed on the second buffer layer 112.

In an embodiment, the semiconductor layer A1 may include amorphous silicon or polycrystalline silicon. In an alternative embodiment, the semiconductor layer A1 may include an oxide of at least one selected from indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In another alternative embodiment, the semiconductor layer A1 may include Zn-oxide-based material and include Zn-oxide, In—Zn oxide, and Ga—In—Zn oxide. In another alternative embodiment, the semiconductor layer A1 may include In—Ga—Zn—O (IGZO), In—Sn—Zn—O (ITZO), or In—Ga—Sn—Zn—O (IGTZO) semiconductor containing metal such as indium (In), gallium (Ga), and stannum (Sn) in ZnO. The semiconductor layer A1 may include a channel region, a drain region, and a source region, where the drain region and the source region are respectively on two opposite sides of the channel region. The semiconductor layer A1 may have a single-layered structure or a multi-layered structure.

The second metal layer ML2 may be arranged along the shape of the trench TR. A portion of the second metal layer ML2 may be disposed inside the trench TR. That is, the second metal layer ML2 may overlap the trench TR. The second metal layer ML2 may be the second electrode CE2 of the capacitor Cst. The second metal layer ML2 may be connected to the connection electrode layer CM through a contact hole CNT3. The second metal layer ML2 may be connected to the data line DL.

The second metal layer ML2 may include a material having high conductivity. The second metal layer ML2 may include a same metal as a metal of the connection electrode layer CM described below. Accordingly, the second metal layer ML2 may secure high contact resistance and processibility. In an embodiment, for example, the second metal layer ML2 may include titanium (Ti). In an embodiment where the second metal layer ML2 includes titanium (Ti), adhesion may be improved.

A filling layer FL may be disposed on the second metal layer ML2. The filling layer FL may fill a region on the second metal layer ML2 corresponding to the trench TR. The filling layer FL may planarize an unevenness generated when the first buffer layer 111, the first metal layer ML1, the second buffer layer 112, the second metal layer ML2 disposed on the substrate 100 are provided in the form of the trench TR.

The filling layer FL may include a spin-on-glass (SOG) material. The SOG is a composite material of an organic material and an inorganic material having a mixed cage-network structure, and is a material converted into SiO₂ through annealing at a temperature of about 400° C. or higher. The filling layer FL may be formed by spin coating. In the case where the filling layer FL includes an SOG material, high-temperature heat resistance may be improved.

In addition, a process may be simplified by adopting an SOG material that relatively simply forms a layer through coating and baking compared to using a chemical mechanical polishing (CMP) to planarize unevenness formed by the trench TR.

In an embodiment, an SOG material may include silica and an organic material. In such an embodiment, the organic material may be siloxane-based compound or a photosensitive polyimide (PSPI). Alternatively, an SOG material may include silicate, siloxane, methyl silsequioxane (MSQ), hydrogen silsequioxane (HSQ), perhydropolysilazane ((SiH₂NH)ₙ)), polysilazane or a mixture thereof.

The gate electrode G1 may be disposed on the semiconductor layer A1 with the gate insulating layer 113 therebetween to overlap the semiconductor layer A1 at least partially. The gate electrode G1 may include at least one selected from molybdenum (Mo), aluminum (Al), copper (Cu), titanium (Ti) and the like and may have a single-layered structure or a multi-layered structure. In an embodiment, for example, the gate electrode G1 may include a single Mo layer.

An interlayer insulating layer 115 may be provided to cover the gate electrode G1. The interlayer insulating layer 115 may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO or ZnO₂).

The connection electrode layer CM may be disposed on the interlayer insulating layer 115. The connection electrode layer CM may include the source electrode S1, the drain electrode D1, and the data line DL. The source electrode S1 and the drain electrode D1 may be connected to a source region or a drain region of the semiconductor layer A1 through contact holes CNT1 and CNT2. The connection electrode layer CM may be connected to the second metal layer ML2 through the contact hole CNT3. The data line DL included in the connection electrode layer CM may be electrically connected to the second metal layer ML2.

The connection electrode layer CM may include a conductive material including molybdenum (Mo), aluminum (Al), copper (Cu), or titanium (Ti) and have a single-layered structure or a multi-layered structure, each layer therein including at least one selected from the above materials. In an embodiment, for example, the connection electrode layer CM may have a multi-layered structure of Ti/Al/Ti. In such an embodiment, because the second metal layer ML2 connected to the connection electrode layer CM through the contact hole CNT3 includes titanium (Ti) which is the same material as a material of the connection electrode layer CM, high contact resistance and processibility may be secured and adhesion may be improved.

Referring to FIG. 3, the display apparatus according to an embodiment may include the substrate 100 including the trench TR, the capacitor Cst disposed on the substrate 100, the bottom metal layer BML, and the thin-film transistor T1 disposed on the bottom metal layer BML. The thin-film transistor T1 may include the source electrode S1, the semiconductor layer A1, the drain electrode D1, and the gate electrode G1.

The capacitor Cst may include the first metal layer ML1, the second metal layer ML2, and the inorganic insulating layer IIL, where the first metal layer ML1 is disposed on the shape of the trench TR, the second metal layer ML2 is disposed on the first metal layer ML1 along the shape of the trench TR, and the inorganic insulating layer IIL is disposed between the second metal layer ML2 and the first metal layer ML1. The first metal layer ML1 may be disposed in (or directly on) a same layer as the bottom metal layer BML.

In an embodiment, as shown in FIG. 3, the inorganic insulating layer IIL may be a portion of the second buffer layer 112 or integrally formed with the second buffer layer 112 as a single unitary and indivisible part, but not being limited thereto. Alternatively, the inorganic insulating layer IL may be a layer provided separately from the second buffer layer 112. The inorganic insulating layer IIL may include silicon oxide (SiOₓ) or silicon nitride (SiNₓ).

The first metal layer ML1 may overlap the second metal layer ML2. The first metal layer ML1 may be the first electrode CE1 of the capacitor Cst, and the second metal layer ML2 may be the second electrode CE2 of the capacitor Cst. The first metal layer ML1 and the second metal layer ML2 may constitute a capacitance with the inorganic insulating layer IIL therebetween. In such an embodiment, the inorganic insulating layer IIL may serve as a dielectric layer of the capacitor Cst.

In such an embodiment, because the first metal layer ML1 and the second metal layer ML2 are disposed along the shape of the trench TR, the surface area of the capacitor Cst may be increased.

In such an embodiment, because the first metal layer ML1 and the second metal layer ML2 are provided three-dimensionally along the unevenness formed by the trench TR, the surface area of the capacitor Cst may be increased compared to a case of a general two-dimensional structure. Referring to FIG. 3, in the case where the capacitor Cst is formed in a first area CA, the surface area of the capacitor Cst may be wider when the first metal layer ML1 and the second metal layer ML2 are disposed along the shape of the trench TR compared to the case where the first metal layer ML1 and the second metal layer ML2 are disposed two-dimensionally in parallel to the substrate 100. Accordingly, in such an embodiment, the capacitance of the capacitor Cst may be increased.

That is, because the display apparatus according to an embodiment includes the trench TR overlapping the first metal layer ML1 and the second metal layer ML2, a capacitance of the capacitor Cst may be increased depending on a depth TH of the trench TR. In addition, a cross-sectional area of the first metal layer ML1 is increased and the resistance of the first metal layer ML1 may be reduced.

In such an embodiment, because the capacitor Cst is formed by using a same layer as the bottom metal layer BML which is a metal layer disposed in the lowermost portion of the display apparatus, limitation in designing the location of the capacitor Cst by other wirings may be reduced.

A planarization layer 118 may be disposed on the connection electrode layer CM, and the organic light-emitting element OLED may be disposed on the planarization layer 118.

The planarization layer 118 may provide a flat upper surface and have a single-layered structure or a multi-layered structure, each layer therein including an organic material. The planarization layer 118 may include a general-purpose polymer such as benzocyclobutene (BCB), polyimide, hexamethyldisiloxane (HMDSO), polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The organic light-emitting element OLED is disposed on the planarization layer 118 in the display area DA of the substrate 100. The organic light-emitting element OLED includes a pixel electrode 310, an intermediate layer 320, and an opposite electrode 330, where the intermediate layer 320 includes an organic emission layer.

The pixel electrode 310 may be a (semi) light-transmissive electrode or a reflective electrode. In an embodiment, the pixel electrode 310 may include a reflective layer and a transparent or semi-transparent electrode layer on the reflective layer, wherein the reflective layer includes at least one selected from Ag, Mg, Al, Pt, Pd, Au, Ni, Nd, Ir, Cr, and compound thereof. The transparent or semi-transparent electrode layer may include at least one selected from indium tin oxide (ITO), indium zinc oxide (IZO), zinc oxide (ZnO), indium oxide (In₂O₃), indium gallium oxide (IGO), and aluminum zinc oxide (AZO). In an embodiment, for example, the pixel electrode 310 may include ITO/Ag/ITO.

A pixel-defining layer 119 may be disposed on the planarization layer 118. The pixel-defining layer 119 may define an emission area of a pixel with an opening defined therethrough to correspond to each sub-pixel in the display area DA, that is, with an opening OP defined therethrough to expose at least a central portion of the pixel electrode 310. In addition, the pixel-defining layer 119 may prevent arcs or the like from occurring at the edges of each pixel electrode 310 by increasing a distance between the edges of each pixel electrode 310 and the opposite electrode 330 over the pixel electrode 310.

The pixel-defining layer 119 may include an organic insulating material such as polyimide, an acrylic resin, benzocyclobutene, a phenolic resin or the like, and be formed by using spin coating or the like.

The intermediate layer 320 of the organic light-emitting element OLED may include an organic emission layer. The organic emission layer may include an organic material including a fluorescent or phosphorous material emitting red, green, blue, or white light. The organic emission layer may include a polymer organic material or a low molecular weight organic material. Functional layers may be selectively further arranged under and on the organic emission layer, the functional layers including a hole transport layer (HTL), a hole injection layer (HIL), an electron transport layer (ETL), and an electron injection layer (EIL). The intermediate layer 320 may be disposed to correspond to the plurality of pixel electrodes 310. However, the embodiment is not limited thereto. The intermediate layer 320 may include a layer that is a single unitary and indivisible body over the plurality of pixel electrodes 310. However, various modifications may be made.

The opposite electrode 330 may be a light-transmissive electrode or a reflective electrode. In an embodiment, the opposite electrode 330 may be a transparent or semi-transparent electrode and may include a thin metal film including Li, Ca, LiF/Ca, LiF/Al, Al, Ag, Mg, or compound thereof and having a small work function. In addition, a transparent conductive oxide (TCO) layer such as ITO, IZO, ZnO, or In₂O₃ may be further arranged on the thin metal film. The opposite electrode 330 may be arranged over the display area DA and the peripheral area PA, and disposed on the intermediate layer 320 and the pixel-defining layer 119. The opposite electrode 330 may be formed as a single unitary and indivisible body over the plurality of organic light-emitting elements to correspond to the plurality of pixel electrodes 310.

A spacer 119S for preventing mask chopping may be further disposed on the pixel-defining layer 119. The spacer 119S may be integrally formed with the pixel-defining layer 119. In an embodiment, for example, the spacer 119S and the pixel-defining layer 119 may be simultaneously formed during a same process that uses a half-tone mask process.

Because the organic light-emitting element OLED may be easily damaged by external moisture, oxygen, or the like, the organic light-emitting element OLED may be protected by being covered by the thin-film encapsulation layer 400. The thin-film encapsulation layer 400 may cover the display area DA and extend to the outside of the display area DA. The thin-film encapsulation layer 400 includes at least one organic encapsulation layer and at least one inorganic encapsulation layer. In an embodiment, for example, the thin-film encapsulation layer 400 includes a first inorganic encapsulation layer 410, an organic encapsulation layer 420, and a second inorganic encapsulation layer 430.

The first inorganic encapsulation layer 410 may cover the opposite electrode 330 and include silicon oxide, silicon nitride, and/or silicon trioxynitride. Though not shown, other layers such as a capping layer may be disposed between the first inorganic encapsulation layer 410 and the opposite electrode 330 when desired. Because the first inorganic encapsulation layer 410 is formed along a structure thereunder, an upper surface thereof is not flat. The organic encapsulation layer 420 may cover the first inorganic encapsulation layer 410, and unlike the first inorganic encapsulation layer 410, the upper surface of the organic encapsulation layer 420 may be approximately flat. Specifically, the upper surface of a portion of the organic encapsulation layer 420 that corresponds to the display area DA may be approximately flat. The organic encapsulation layer 420 may include at least one material selected from polyethylene terephthalate, polyethylene naphthalate, polycarbonate, polyimide, polyethylene sulfonate, polyoxymethylene, and polyarylate, hexamethyldisiloxane. The second inorganic encapsulation layer 430 may cover the organic encapsulation layer 420 and include silicon oxide, silicon nitride, and/or silicon trioxynitride.

Even when cracks occur inside the thin-film encapsulation layer 400, the thin-film encapsulation layer 400 may prevent the cracks from being connected between the first inorganic encapsulation layer 410 and the organic encapsulation layer 420 or between the organic encapsulation layer 420 and the second inorganic encapsulation layer 430 through the above multi-layered structure. in such an embodiment, forming of a path through which external moisture or oxygen penetrates the display area DA may be effectively prevented or substantially reduced.

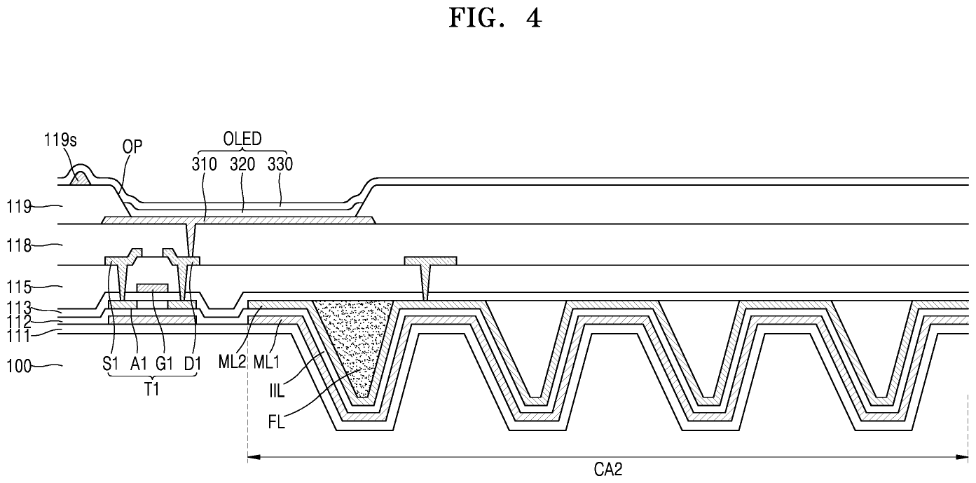

FIG. 4 is a schematic cross-sectional view of a display apparatus according to an alternative embodiment. In FIG. 4, the same reference numerals as those of FIG. 3 denote the same members, and thus, any repetitive detailed descriptions thereof are omitted.

Referring to FIG. 4, the display apparatus according to an embodiment may include the substrate 100 including the trench TR, the capacitor Cst disposed inside the trench TR, the bottom metal layer BML apart from the capacitor Cst, and the thin-film transistor T1 disposed on the bottom metal layer BML. The capacitor Cst may include the first metal layer ML1, the inorganic insulating layer IIL, and the second metal layer ML2, wherein the first metal layer ML1 is disposed in (or directly on) a same layer as the bottom metal layer BML, and the inorganic insulating layer IIL and the second metal layer ML2 overlap the first metal layer ML1.

According to an embodiment, the substrate 100 may include a plurality of trenches TR. The first metal layer ML1 and the second metal layer ML2 may be arranged along the shape of the trenches TR. The first metal layer ML1 and the second metal layer ML2 may be arranged inside the trenches TR.

The inorganic insulating layer IIL may be disposed between the first metal layer ML1 and the second metal layer ML2. Like the first metal layer ML1 and the second metal layer ML2, the inorganic insulating layer IIL may be disposed along the shape of the plurality of trenches TR. The inorganic insulating layer IIL may be disposed inside the trenches TR. In an embodiment, as shown in FIG. 4, the inorganic insulating layer IIL may be a part of the second buffer layer 112, but not being limited thereto. Alternatively, the inorganic insulating layer IIL may be a layer provided separately from the second buffer layer 112. The inorganic insulating layer IIL may include silicon oxide (SiOₓ) or silicon nitride (SiNₓ).

The first metal layer ML1 and the second metal layer ML2 may overlap each other and constitute a capacitance. In such an embodiment, the inorganic insulating layer IIL between the first metal layer ML1 and the second metal layer ML2 may serve as a dielectric layer.

Referring to FIG. 4, the first metal layer ML1 and the second metal layer ML2 may be disposed along the shape of the plurality of trenches TR to increase the surface area. In such an embodiment, even in a case where the depth TH of the trench TR is as the same as that shown in the embodiment of FIG. 3, the surface area is further increased as the plurality of trenches TR are provided. In such an embodiment, even in a case where the first area CA1 of FIG. 3 is the same region as a second area CA2 of FIG. 4, that is, when the number of trenches TR increases in a region in a same area, the surface area thereof may be further increased.

In an embodiment, a filling layer FL disposed on the second metal layer ML2 and filling a region corresponding to the trench TR may be further provided. The filling layer FL may be configured to fill the plurality of trenches TR. The filling layer FL may include an SOG material.

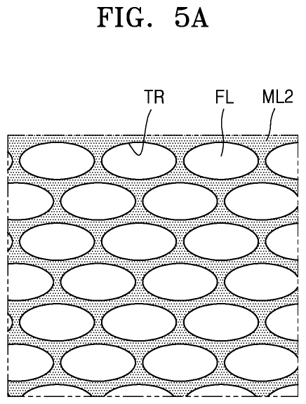

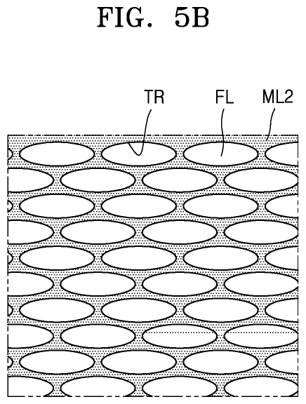

FIGS. 5A and 5B are plan views of a display apparatus according to embodiments. The trench TR may be provided in an elliptical shape in a plan view or when viewed in a thickness direction of the substrate 100. FIGS. 5A and 5B show a plane in an embodiment including a plurality of trenches TR, where each trench TR has an elliptical planar shape. A plurality of elliptical shapes in FIGS. 5A and 5B may be apart from each other. In FIGS. 5A and 5B, the inside of the elliptical shape represents the filling layer FL including an SOG material, and the outside of the elliptical shape represents the second metal layer ML2.

As shown in FIGS. 5A and 5B, in an embodiment where the trench TR is provided in an ellipse, not a circle in the same region, the trenches TR may be more densely arranged due to the characteristics of the ellipse having a difference in length between a major axis and a minor axis. Particularly, in an embodiment where the trench TR is provided in a squeezed ellipse in a plan view as shown in FIG. 5B compared to FIG. 5A, the trenches TR may be more densely arranged. An ellipse squeezed more than the ellipse of FIG. 5A means a shape in which the ellipse of FIG. 5 is pressed in a minor axis direction. This may mean a shape in which the length of the minor axis of the ellipse is reduced even more.

in an embodiment, because the trench TR is provided in an elliptical shape in a plan view, the surface area of the capacitor Cst including the first metal layer ML1 and the second metal layer ML2 may be increased. Accordingly, the capacitance may be further increased. Alternatively, the trench TR may be provided in a shape such as a circle or a polygon, not an ellipse in a plan view.

The display apparatus according to an embodiment may include an increased capacitance of the capacitor by including the substrate 100, the first metal layer ML1, the inorganic insulating layer IIL, and the second metal layer ML2 that are sequentially disposed along the shape of the trench TR, where the substrate 100 includes the trench TR. In such an embodiment, an increase in the capacitance may be maximized by providing a plurality of trenches TR or providing the shape of the trench TR in an elliptical shape in a plan view. Because the first metal layer ML1 is disposed in a same layer as the bottom metal layer BML, which is the lowermost metal layer, a limitation in the design of the capacitor may be reduced.

According to an embodiment, the display apparatus in which the capacitance of the capacitor is sufficiently secured and which prevents deterioration in image quality may be provided.

The invention should not be construed as being limited to the embodiments set forth herein. Rather, these embodiments are provided so that this disclosure will be thorough and complete and will fully convey the concept of the invention to those skilled in the art

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a substrate including a trench;
a capacitor disposed on the substrate in the trench;
a bottom metal layer disposed on the substrate and spaced apart from the capacitor; and
a thin-film transistor disposed on the bottom metal layer,
wherein the capacitor includes a first metal layer, a second metal layer, and an inorganic insulating layer,
the first metal layer is disposed in a same layer as the bottom metal layer,
the second metal layer disposed on the first metal layer, and
the inorganic insulating layer is disposed between the first metal layer and the second metal layer.

2. The display apparatus of claim 1, wherein a portion of the capacitor has a shape corresponding to a shape of the trench.

3. The display apparatus of claim 1, wherein the second metal layer includes titanium (Ti).

4. The display apparatus of claim 1, further comprising:
a filling layer disposed on the second metal layer and filling a region on the second metal layer corresponding to the trench,
wherein the filling layer includes a spin-on-glass (SOG) material.

5. The display apparatus of claim 1, wherein the trench has an elliptical shape in a plan view.

6. The display apparatus of claim 1, wherein the trench is provided in plural.

7. The display apparatus of claim 6, wherein
each of a plurality of trenches has an elliptical shape in a plan view, and
the trenches are apart from each other in the plan view.

8. The display apparatus of claim 1, wherein the second metal layer is connected to a connection electrode layer disposed on the thin-film transistor through a contact hole.

9. The display apparatus of claim 8, wherein
the connection electrode layer includes a data line, and
the second metal layer is electrically connected to the data line.

10. The display apparatus of claim 1, wherein the thin-film transistor includes an oxide semiconductor.

11. A display apparatus comprising:
a substrate including a trench;
a capacitor on the substrate, wherein the capacitor includes a first metal layer, an inorganic insulating layer, and a second metal layer sequentially disposed on the substrate along a shape of the trench; and
a filling layer disposed on the second metal layer and filling a region on the second metal layer corresponding to the trench,
wherein the filling layer includes a spin-on-glass (SOG) material.

12. The display apparatus of claim 11, further comprising:
a thin-film transistor disposed on the substrate.

13. The display apparatus of claim 12, wherein the thin-film transistor includes an oxide semiconductor.

14. The display apparatus of claim 13, further comprising:
a bottom metal layer between the substrate and the thin-film transistor.

15. The display apparatus of claim 14, wherein the first metal layer is disposed in a same layer as the bottom metal layer.

16. The display apparatus of claim 12, further comprising:
a connection electrode layer disposed on the second metal layer and the thin-film transistor, wherein the connection electrode layer is electrically connected to the second metal layer.

17. The display apparatus of claim 16, wherein the second metal layer includes a same material as a material of the connection electrode layer.

18. The display apparatus of claim 11, wherein the trench is provided in plural.

19. The display apparatus of claim 18, wherein
each of a plurality of trenches has an elliptical shape in a plan view, and
the trenches are apart from each other in the plan view.

20. The display apparatus of claim 16, further comprising:
a pixel electrode disposed on the connection electrode layer;
a pixel-defining layer disposed on the pixel electrode, wherein an opening is defined through the pixel-defining layer to expose a portion of the pixel electrode;
an intermediate layer filling the opening; and
an opposite electrode disposed on the intermediate layer.
